(19) United States
(12) Patent Application Publication
(10) Pub. No.: US 2009/0001430 A1
(43) Pub. Date: Jan. 1, 2009

(54) ELIMINATE NOTCHING IN SI POST SI-RECESS RIE TO IMPROVE EMBEDDED DOPED AND INSTRINSIC SI EPITAZIAL PROCESS

(75) Inventors: Ashima B. Chakravarti, Hopewell Junction, NY (US); Renee T. Mo, Briarcliff Manor, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/771,013

(22) Filed: Jun. 29, 2007

(51) Int. Cl. H01L 29/78; H01L 21/336

(52) U.S. Cl. 257/288; 438/300; 257/E29.255; 257/E21.409

(57) ABSTRACT

A dielectric element, and method of manufacturing the same, is disclosed for a semiconductor structure which comprises a substrate having a gate formed on a top surface of the substrate. The substrate and gate define a gap in a region between the gate and the substrate. A specified amount of dielectric on the substrate, at least a portion of which is in the gap, forms the dielectric element which substantially prevents unwanted electrical connectivity between the gate and the substrate.

### FIELD OF THE INVENTION

This invention relates to a method of fabricating a metal oxide semiconductor field effect transistor, and more particularly, a method of fabricating a metal oxide semiconductor field effect transistor such that a notch created during isotropic or anisotropic etching of Si and/or precleaning is substantially filled.

### BACKGROUND OF THE INVENTION

During CMOS (complementary metal-oxide semiconductor) processing, in order to derive maximum stress benefit to a channel region of a substrate or wafer, an anisotropic recess is formed with a very narrow spacer. Thereafter, the recess is filled with epitaxial SiGe or SiC or other strain inducing epitaxial films.

Typically, the epitaxial growth process requires very stringent surface conditions of the substrate for the best and most consistent results. A high quality surface that is free of contamination requires that the wafers be pre-cleaned extensively. For example, a polysilicon gate having spacers on opposing sides may be formed over a gate dielectric on a Si (Silicon) substrate. During pre-clean steps, the corners of the substrate under the spacers are exposed to the pre-clean. The exposure can form a gap or notch between the spacers and the substrate. The gap or notch may extend between the gate polysilicon and substrate causing a gate source/drain short after the epitaxial film has been deposited. Process variability, with the Si recess etch, line edge roughness beneath the spacer, and pre-clean oxide removal oxide etch, can lead to sporadic leakage variation and manufacturing process repeatability issues.

A known semiconductor process for forming, for example, a gate on a substrate during CMOS fabrication is shown in FIGS. 1a-1d and 2a-2d. Referring to FIGS. 1a-1d, a prior art method 10 of semiconductor manufacturing includes an anisotropic Si recess 16 and a gate 14 formed of a conductor material 20 (for example, of polysilicon or SiGe) and a gate dielectric 24 that are located on a substrate 18. The gate 14 includes sidewall spacers 22 (comprising a dielectric, for example, a nitride) and is formed over the sidewall dielectric layer 24. The gate 14 is shown in FIG. 1b after being processed for removal of organic contamination to substantially prevent defects. During cleaning, undesirable etching away of the dielectric 24 beneath the spacers 22 and the gate 14 as shown in FIGS. 1c and 1d occurs, forming a gap or notch 26. As can be seen in FIG. 1d, the gap 26 includes a portion 28 under the dielectric spacer 22, and a portion 30 under the gate conductor 20. Further, during processing, the recess 16 will be filled with a strain inducing material, for example SiGe, Si:C, doped SiGe, or doped polysilicon (not shown) including the gap 26 and thus, a short can occur between the gate conductor 20 and the filled recess 16.

Similarly, referring to FIGS. 2a-2d, a prior art method 50 of semiconductor manufacturing includes an isotropic Si recess 56 and a gate 54 formed of a conductor material 60 (for example, a silicon compound) and a gate dielectric 64 are located on a substrate 58. The recess 56 includes arcuate region 56a in contrast to recess 16 shown in FIGS. 1a-1c. The gate 54 also includes sidewall spacers 62 (comprising a dielectric or for example a nitride) and is formed over a dielectric 64. The gate 54 is shown in FIG. 2b after being processed for removal of organic contamination to substantially prevent defects. During processing, undesirable etching away of the gate dielectric 64 occurs beneath the spacers 62 and the gate 54 as shown in FIGS. 2c and 2d forming a gap or notch 72. The gap 72 includes a region 74 beneath the spacer 62 and region 76 beneath the gate conductor 60. Similarly, with the prior art embodiment shown in FIGS. 1a-1d, the recess 56 will be filled with a conductor, and thus, a short can occur between the gate conductor 60 and the filled recess 56.

It would therefore be desirable to provide a semiconductor manufacturing method which substantially reduces or eliminates the gap or notch which results in the gate being vulnerable to source/drain shorts or leakage.

### SUMMARY OF THE INVENTION

In an aspect of the present invention, a semiconductor structure for semiconductor fabrication comprises a substrate having a top surface and at least one gate located on the top surface. The substrate and gate define a gap in a region between the gate and the substrate. At least a portion of a specified amount of dielectric on the substrate, at least a portion of which is in the gap, which forms a dielectric element that substantially prevents unwanted electrical connectivity between the gate and the substrate.

In a related aspect, the dielectric element is substantially positioned in the gap.

In a related aspect, the gap is at least partially beneath the gate.

In a related aspect, the dielectric element is substantially beneath the gate.

In a related aspect, a region of the substrate is at least partially beneath the gate, and the dielectric element is on a top surface of the region of the substrate and substantially beneath the gate.

In a related aspect, the substrate includes a dopant.

In a related aspect, the gate includes spacers positioned on opposing side walls of the gate.

In a related aspect, the gap and the dielectric element are both at least partially beneath the spacer.

In a related aspect, the gate includes a gate conductor.

In a related aspect, the gate includes a semiconductor gate.

In a related aspect, the dielectric element is an oxide.

In a related aspect, the structure includes a plurality of gates, and the substrate is anisotropically recessed between the gates.

In a related aspect, the structure includes a plurality of gates, and the substrate is isotropically recessed between the gates.

In a related aspect, a plurality of gates and a multiplicity of corresponding gaps between the gates and the substrate, and the gaps are substantially filled by a plurality of dielectric elements.

In a related aspect, the substrate further comprises a source region and a drain region in the substrate on opposing sides of the gate, and the dielectric element substantially prevents unwanted electrical connectivity between the gate and the source and drain regions.

In a related aspect, the gate is a field-effect transistor.

In another aspect of the present invention, a semiconductor structure for semiconductor fabrication comprising a substrate having a top surface and a plurality of gates located on the top surface. A recess in the substrate is formed between the gates either isotropically or anisotropically, and the substrate and the gates define a gap in a region between the gate and the substrate. A specified amount of dielectric is on the substrate, at least a portion of which, is in the gap forming a dielectric element which substantially prevents unwanted electrical connectivity between the gate and the substrate.

In a related aspect, the gate includes sidewall spacers and multiple gaps which are substantially beneath the gate and the sidewall spacers. A plurality of dielectric elements substantially fill the gaps beneath the gates and the sidewall spacers.

In another aspect of the present invention, a method for processing a semiconductor structure during semiconductor fabrication comprises providing a substrate having a top surface, and forming at least one gate on the top surface and recessed regions in the substrate on opposite sides of the gate. The substrate and gate define a gap in a region between the gate and the substrate. A dielectric layer is formed over the substrate, gate and recessed regions and then removed leaving a dielectric element at least a portion of which is in the gap between the substrate and gate to substantially prevent unwanted electrical connectivity between the gate and the substrate.

In a related aspect, the method further comprises forming a source region and a drain region in the substrate on opposing sides of the gate. The dielectric element substantially prevents unwanted electrical connectivity between the gate and the source and drain regions.

In a related aspect, the dielectric layer is removed by etching.

In a related aspect, the method further includes forming a recess in the substrate between multiple gates. The recess is either isotropic or anisotropic.

In a related aspect, the method further comprises cleaning the substrate before the step of forming the dielectric layer over the substrate.

In a related aspect, the method further comprises forming a recess in the substrate and cleaning the substrate. The steps of forming a recess and cleaning the substrate erode a dielectric layer from between the substrate and the gate to form at least one gap.

In a related aspect, the method further comprises filling the at least one gap by the steps of forming the dielectric layer over the substrate and removing the dielectric layer.

### BRIEF DESCRIPTION OF THE DRAWINGS

These and other objects, features and advantages of the present invention will become apparent from the following detailed description of illustrative embodiments thereof, which is to be read in connection with the accompanying drawings, in which:

FIG. 1a is a cross sectional side elevational view depicting a prior art substrate and gate having spacers during semiconductor processing where the substrate includes an anisotropic recess;

FIG. 1b is a cross sectional side elevational view of the process shown in FIG. 1a depicting removing contaminants with a pre-clean during semiconductor processing;

FIG. 1c is a cross sectional side elevational view of the process shown in FIGS. 1a and 1b depicting a gap or notch, which occurs as a result of the pre-clean, beneath the gate and spacers;

FIG. 1d is a detail view of the gate, spacer, and gap shown in FIG. 1c;

FIG. 2a is a cross sectional side elevational view depicting a prior art substrate and gate having spacers during semiconductor processing where the substrate includes an isotropic recess;

FIG. 2b is a cross sectional side elevational view of the process shown in FIG. 2a depicting removing contaminants with a pre-clean during semiconductor processing;

FIG. 2c is a cross sectional side elevational view of the process shown in FIGS. 2a and 2b depicting a gap or notch, which occurs as a result of the pre-clean, beneath the gate and spacers;

FIG. 2d is a detail view of the gate, spacer, and gap shown in FIG. 2c;

FIG. 3 is a cross sectional side elevational view depicting a method for semiconductor processing according to an embodiment of the invention showing two gates having sidewall spacers on a substrate;

FIG. 4 is a cross sectional side elevational view depicting anisotropic recesses in the substrate shown in FIG. 3;

FIGS. 5a and 5b are a cross sectional side elevational view of a gate shown in FIG. 4 and a detail view of the same, respectively, depicting a gap between the gate and spacers, and the substrate;

FIG. 6 is a cross sectional side elevational view depicting a dielectric layer on the substrate shown in FIGS. 3 and 4;

FIG. 7 is a cross sectional side elevational view depicting the dielectric layer shown in FIG. 5 removed and dielectric elements filling gaps between the substrate and the gates and the spacers;

FIG. 8 is a cross sectional side elevational view depicting a method for semiconductor processing according to another embodiment of the invention including two gates having sidewall spacers on a substrate;

FIG. 9 is a cross sectional side elevational view depicting isotropic recesses in the substrate shown in FIG. 8;

FIGS. 10a and 10b are a cross sectional side elevational view of the gate shown in FIG. 9 and a detail view of the same, respectively, depicting a gap between the gate and spacers, and the substrate;

FIG. 11 is a cross sectional side elevational view depicting a dielectric layer on the substrate shown in FIGS. 8 and 9; and

FIG. 12 is a cross sectional side elevational view depicting the dielectric layer shown in FIG. 11 removed and dielectric elements filling gaps between the substrate and the gates and the spacers.

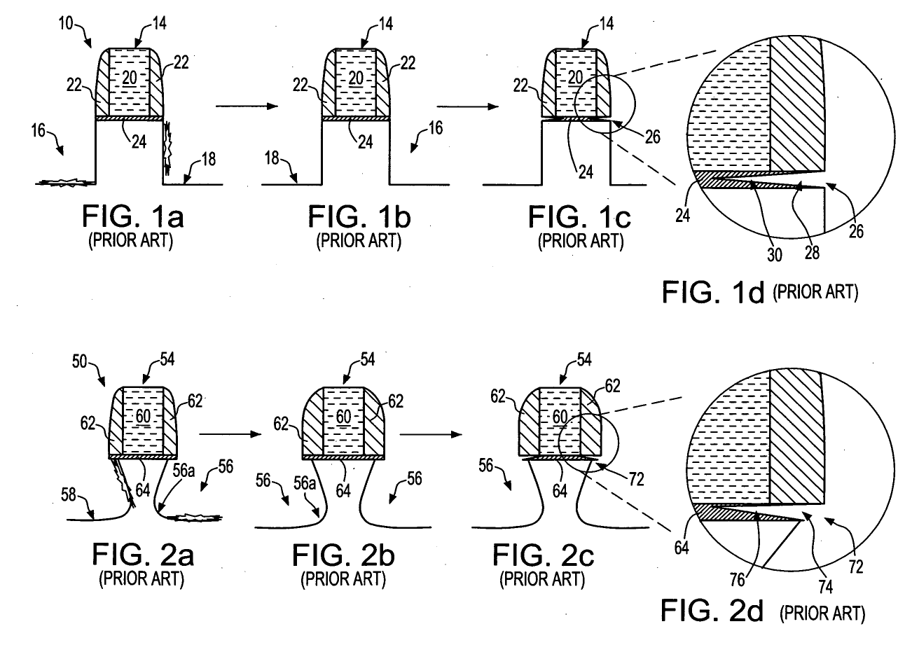

### DETAILED DESCRIPTION OF THE INVENTION

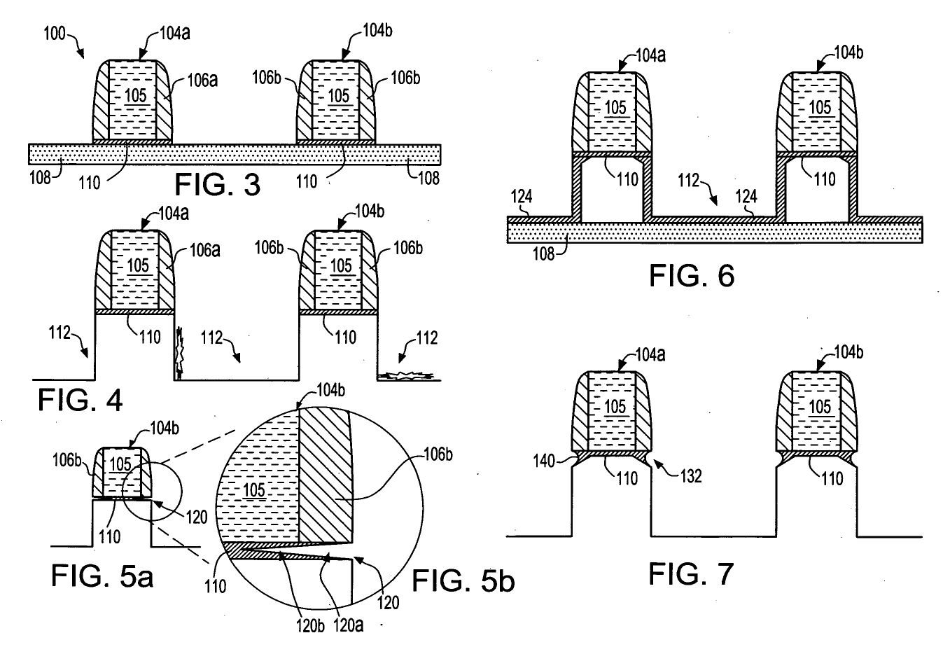

According to the present invention, an illustrative embodiment of a method 100 for processing a semiconductor substrate is shown in FIG. 3 which includes gates 104a, 104b formed of a conductor material 105 (for example, polysilicon or a SiGe) and having sidewall spacers 106a and 106b, respectively, both formed over a dielectric layer 110. The dielectric layer 110 is positioned in a region between the substrate 108 (which may be a silicon alloy) and the gates 104a, 104b and the sidewall spacers 106a, 106b. The gates may be, for example, field-effect transistors.

Referring to FIG. 4, anisotropic recesses 112 are formed in the substrate 108. During CMOS fabrication, the substrate 108 may be recessed by an etching process such as RIE (reactive ion etching), and/or an aqueous chemical etch. The etching process can form an undercut, gap, or notch 120 beneath each of the spacers 106a, 106b, as well as, the gates 104a, 104b. The recesses will be filled with epitaxial material, such as, SiGe, SiC, or other strain inducing epitaxial films (not shown). The epitaxial growth process requires very stringent surface conditions for the best and most consistent results. A high quality surface that is free of contamination requires that the wafers be pre-cleaned extensively.

Referring to FIG. 5, the substrate recess regions 112 may have multiple exposed crystallographic orientations and an inconsistent and highly variable amount of contamination, such as RIE residue. In order to remove this residue and grow a uniform and consistent epitaxial film, a pre-clean technique is implemented as shown in FIG. 5, which depicts gate 104b for illustrative purposes. The substrate etching and pre-clean causes erosion of the dielectric layer 110 in a region between the gate 104b and the substrate 108, and thereby gap 120 having a gap portion 120a under the sidewall spacers 106b and a gap portion 120b under the gate 104b, as shown in FIGS. 5a and 5b, is formed.

In contrast to the prior art, the method according to the present invention includes forming a sacrificial dielectric layer 124 (on the substrate 108), as shown in FIG. 6. Dopants may be present at this point in the process flow, thus, preferably, forming the dielectric layer 124 should occur at a low temperature, such as below 600° Celsius. The dielectric layer 124 may be formed using plasma oxidation. The dielectric layer 124 fills the gap 120 under the gates 104a, 104b and sidewall spacers 106a, 106b. The dielectric layer 124, is formed over the surface of the substrate and is thicker in the corners where the sidewall spacers and the substrate meet, hence, during the removal of the sacrificial layer 124 along the planar surfaces of the substrate 108, a small amount of the dielectric 124 is left to form oxide elements (or dielectric elements) 140, as shown in FIG. 7.

Thus, during the removal of the layer 124, a region beneath the gates 104a, 104b and the side wall spacers 106a, 106b defined by a gap are untouched, and thus the dielectric remains in place in the gap from the dielectric layer 124 to form oxide elements 140, as shown in FIG. 7. The oxide elements 136 left around the spacers 106a, 106b are beneficial in protecting the gate dielectric while having no detrimental effects on subsequent semiconductor processing of the substrate. Oxide element 136 protects the gate dielectric 104a, 104b from exposure to etch chemistries during subsequent processes. Thus, the method is applied in the semiconductor processing before the recesses are filled with epitaxial silicon compounds, such as, SiGe, SiC, or other strain inducing epitaxial films (not shown).

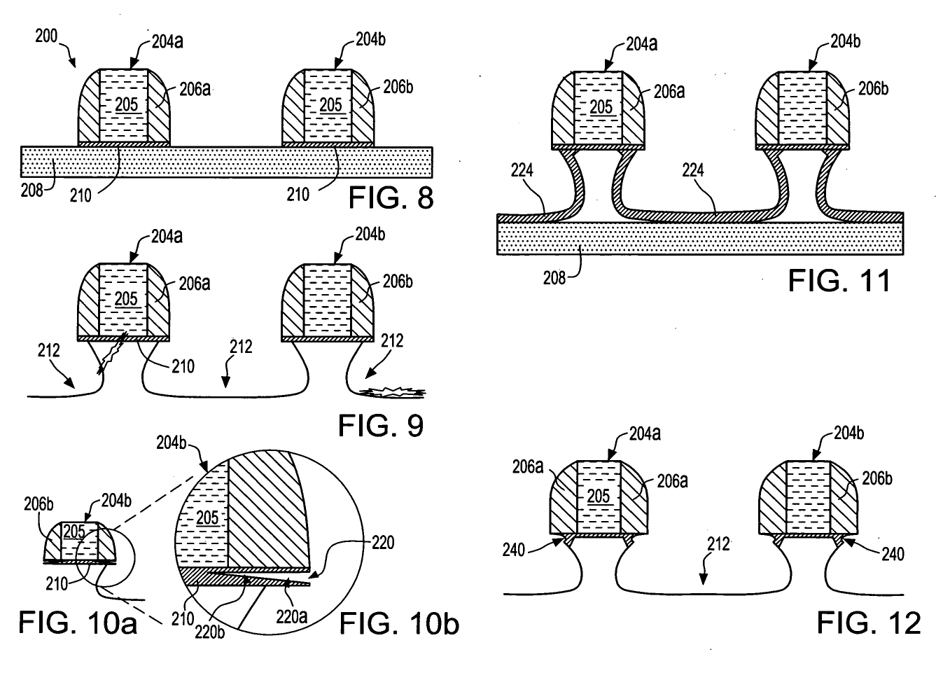

Referring to FIG. 8, another illustrative embodiment of the method 200 according to the present invention is shown for processing a semiconductor substrate which includes two gates 204a, 204b including conductor material 205 and having spacers 206a and 206b, respectively, both formed on a gate dielectric 210 located on substrate 208. The gates 204a, 204b may be formed of typical materials used in known semiconductor processing techniques.

Referring to FIG. 9, isotropic recesses 212 are formed in the substrate 208, for example, by etching. As discussed above regarding the embodiment shown in FIGS. 3-7, during CMOS fabrication, the substrate 208 is recessed by an etching process which can form an undercut, gap, or notch 220 beneath each of the sidewall spacers 206a, 206b, as well as, the gates 204a, 204b. In the substrate shown in FIG. 9, an isotropic etch can propagate beneath the spacers while forming the recesses. A high quality surface that is free of contamination requires that the wafers be pre-cleaned extensively to allow epitaxial growth. The substrate 208 recess regions 212 may have multiple exposed crystallographic orientations and an inconsistent and highly variable amount of contamination, such as RIE residue or other organic physisorbed contaminants. In order to remove this residue and grow a uniform and consistent epitaxial film, a pre-clean technique is implemented as shown in FIG. 9. The pre-clean and recess etching results in the erosion of dielectric 210, as shown in FIGS. 10a and 10b which depicts gate 204b for illustrative purposes. The substrate etching and pre-clean causes a gap 220 having a gap portion 220a under the sidewall spacers 206b and a gap portion 220b under the gate 204b.

As discussed regarding the previous embodiment shown in FIGS. 3-7, in contrast to the prior art, the method according to the present invention includes forming a sacrificial dielectric layer 224 on the substrate 208, as shown in FIG. 11. The layer 224 is removed before epitaxial growth in the semiconductor process. Dopants may be present at this point in the process flow, thus, preferably, forming the dielectric layer 224 should occur at a low temperature, such as below 600° Celsius. The dielectric layer may be formed using a plasma oxide. The dielectric layer 224 fills the gap 220 under the gates 204a, 204b and sidewall spacers 206a, 206b. The dielectric layer 224, which may be an oxide, is formed over the surface of the substrate 208 and is thicker in the corners where the sidewall spacers and the substrate meet, hence, during the removal of the sacrificial dielectric layer 224 along the planar surfaces of the substrate 208, a small amount of the dielectric 224 is left to form dielectric elements 240, as shown in FIG. 12. The dielectric elements 240 are beneficial in protecting the gates 204a, 204b and spacers 206a, 206b while having no detrimental effects on subsequent semiconductor processing of the substrate, such as exposure to etch chemistries.

While the present invention has been particularly shown and described with respect to preferred embodiments thereof, it will be understood by those skilled in the art that changes in forms and details may be made without departing from the spirit and scope of the present application. It is therefore intended that the present invention not be limited to the exact forms and details described and illustrated herein, but falls within the scope of the appended claims.

1-25. (canceled)

26. A method for processing a semiconductor structure during semiconductor fabrication, comprising:
providing a substrate having a top surface and at least one gate located on the top surface;
recessing regions in the substrate on opposite sides of the at least one gate, the substrate and the at least one gate defining a gap in a region between the at least one gate and the substrate;
forming a dielectric layer over the substrate, the at least one gate and recessed regions;
etching the dielectric layer leaving a dielectric element at least a portion of which is in the gap between the substrate and the at least one gate; and
forming a source region and a drain region in the substrate on opposing sides of the at least one gate, and the dielectric element substantially prevents unwanted electrical connectivity between the at least one gate and the source and drain regions.
